(19) United States
(12) Patent Application Publication
(10) Pub. No.: US 2024/0039184 A1
(43) Pub. Date: Feb. 1, 2024

(54) TERMINAL BLOCK

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Yokkaichi-shi, Mie (JP)

(72) Inventors: Tomoki ABE, Yokkaichi-shi (JP); Takuya HANYU, Yokkaichi-shi (JP); Daisuke HASHIMOTO, Yokkaichi-shi (JP); Masaharu SUETANI, Yokkaichi-shi (JP); Kentaro TACHI, Yokkaichi-shi (JP); Dohyung KIM, Yokkaichi-shi (JP); Yasushi TAMURA, Osaka-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 18/267,541

(22) PCT Filed: Nov. 30, 2021
(86) PCT No.: PCT/JP2021/043819

§ 371 Date: Jun. 15, 2023

(30) Foreign Application Priority Data
Dec. 21, 2020 (JP) 2020-211820

(51) Int. Cl. H01R 9/24

(52) U.S. Cl. CPC H01R 9/2425; H01R 2201/26

(57) ABSTRACT

A terminal block that includes: a first terminal electrically connected to an electrical component; and a second terminal electrically connected to the first terminal, wherein a current sensor for detecting a current that flows through the first terminal or the second terminal is integrated with the first terminal or the second terminal.

### BACKGROUND

The present disclosure relates to a terminal block.

A terminal block equipped with first terminals, which are electrically connected to electrical components such as an inverter and a motor mounted in a vehicle like an automobile, and second terminals, which are electrically connected to the first terminals, is conventionally known. As disclosed in JP 2019-115123A for example, control over the driving of the electrical components is performed by detecting currents flowing through the first terminals or the second terminals using a current sensor.

### SUMMARY

However, when electrical components such as an inverter and a motor are equipped with a current sensor, there will be a corresponding increase in the size of the electrical components due to the inclusion of the current sensor.

An exemplary aspect of the disclosure provides a terminal block that contributes to miniaturization of electrical components.

A terminal block according to an aspect of the present disclosure includes: a first terminal electrically connected to an electrical component, and a second terminal electrically connected to the first terminal, wherein a current sensor for detecting a current that flows through the first terminal or the second terminal is integrated with the first terminal or the second terminal.

A terminal block according to another aspect of the present disclosure includes: a first terminal electrically connected to an electrical component; a second terminal electrically connected to the first terminal; and a housing that is made of resin and holds the second terminal, wherein a current sensor for detecting a current that flows through the second terminal is integrated with the housing.

According to the present disclosure, there is provided a terminal block that is capable of contributing to miniaturization of electrical components.

### BRIEF DESCRIPTION OF THE DRAWINGS

FIG. 1 is a perspective view schematically depicting a state where a terminal block according to a first embodiment has been mounted in a vehicle.

FIG. 2 is a perspective view of the terminal block.

FIG. 3 is a perspective view useful in explaining a junction terminal.

FIG. 4 is a perspective view depicting one part of the terminal block in enlargement.

FIG. 5 is a plan view useful in explaining a current sensor.

FIG. 6 is a cross-sectional view depicting part of the current sensor in enlargement.

FIG. 7 is a perspective view depicting a terminal block according to a second embodiment.

FIG. 8 is a perspective view depicting a terminal block according to a third embodiment.

FIG. 9 is a perspective view depicting a terminal block according to a fourth embodiment.

### DETAILED DESCRIPTION OF EMBODIMENTS

### Outline of Embodiments of the Present Disclosure

Several embodiments of the present disclosure will first be listed and described in outline.

(1) A terminal block according to an aspect of the present disclosure includes: a first terminal electrically connected to an electrical component; and a second terminal electrically connected to the first terminal, wherein a current sensor for detecting a current that flows through the first terminal or the second terminal is integrated with the first terminal or the second terminal.

According to this configuration, since it is not necessary for an electrical component to be provided with a current sensor, a situation where the size of an electrical component increases corresponding to the provision of the current sensor, such as when electrical components are configured to include a current sensor, is avoided. Accordingly, this can contribute to miniaturization of electrical components.

(2) One of the first terminal and the second terminal may include a clip portion, and another of the first terminal and the second terminal may be a bus bar formed as a flat plate that is clamped by the clip portion.

With this configuration, since it is possible to connect the first terminal and the second terminal by merely clamping the bus bar with the clip portion, it is not necessary to provide a separate component for connecting the first terminal and the second terminal, for example, which makes it possible to miniaturize the terminal block itself. In addition, it is possible to easily electrically connect the first terminal and the second terminal while absorbing dimensional tolerances of the first terminal and the second terminal.

(3) The second terminal may include the clip portion, and the first terminal may be a bus bar.

With this configuration, since it is possible to simplify the configuration of the first terminal, it is possible for example to avoid the problem of the designs of components present in the periphery of the first terminal having to be changed due to the configuration of the first terminal being complex.

(4) The bus bar may include a flat plate portion that is surrounded by the current sensor.

With this configuration, since the bus bar includes the flat plate portion that is surrounded by the current sensor, it is easy to integrate the current sensor with the first terminal.

(5) The second terminal may be a bus bar, and the first terminal may include the clip portion.

With this configuration, since it is possible to simplify the configuration of the second terminal, it is possible for example to avoid the problem of the designs of components present in the periphery of the second terminal having to be changed due to the configuration of the second terminal being complex.

(6) The first terminal may include a flat plate portion that extends from the clip portion and is surrounded by the current sensor.

With this configuration, since the first terminal includes a flat plate portion that extends from the clip portion and is surrounded by the current sensor, it is possible to easily integrate the current sensor with the first terminal.

(7) The clip portion may include a pair of clamping portions for clamping the bus bar and a biasing member for biasing the pair of clamping portions toward each other.

With this configuration, due to the biasing member biasing the pair of clamping portions toward each other, it is possible to stably clamp the bus bar with the pair of clamping portions. Accordingly, since it is possible to stabilize the electrical connections between the first terminal and the second terminal, it is possible to improve reliability.

(8) The terminal block may further include a plurality of pairs of the first terminal and the second terminal, and the current sensor may include sensor components, which are provided corresponding to the respective first terminals or the respective second terminals, and a base member that incorporates the plurality of sensor components.

With this configuration, since the current sensor includes a base member incorporating the sensor components provided corresponding to the first terminals or the second terminals, it is possible to simplify the task of disposing the sensor components so as to correspond to the first terminals or the second terminals.

(9) A terminal block according to another aspect of the present disclosure includes: a first terminal electrically connected to an electrical component; a second terminal electrically connected to the first terminal; and a housing that is made of resin and holds the second terminal, wherein a current sensor for detecting a current that flows through the second terminal is integrated with the housing.

With this configuration, since it is not necessary for an electrical component to include a current sensor, a situation where the size of an electrical component increases corresponding to the provision of the current sensor, such as when electrical components are configured to include a current sensor, is avoided. Accordingly, this can contribute to miniaturization of electrical components.

### Detailed Description of the Embodiments of the Disclosure

Specific embodiments of a terminal block according to the present disclosure will now be described with reference to the attached drawings. The present disclosure is not limited to the illustrated configurations and is instead indicated by the range of the patent claims and intended to include all changes within the meaning and scope of the patent claims and their equivalents. Also, for ease of explanation, parts of the configuration may be exaggerated or simplified in the drawings, and the ratios of the dimensions of the respective parts may differ from an actual device. In addition, the ratios of the dimensions of respective parts may differ between drawings.

### First Embodiment

A first embodiment of a terminal block will now be described.

### Overall Configuration

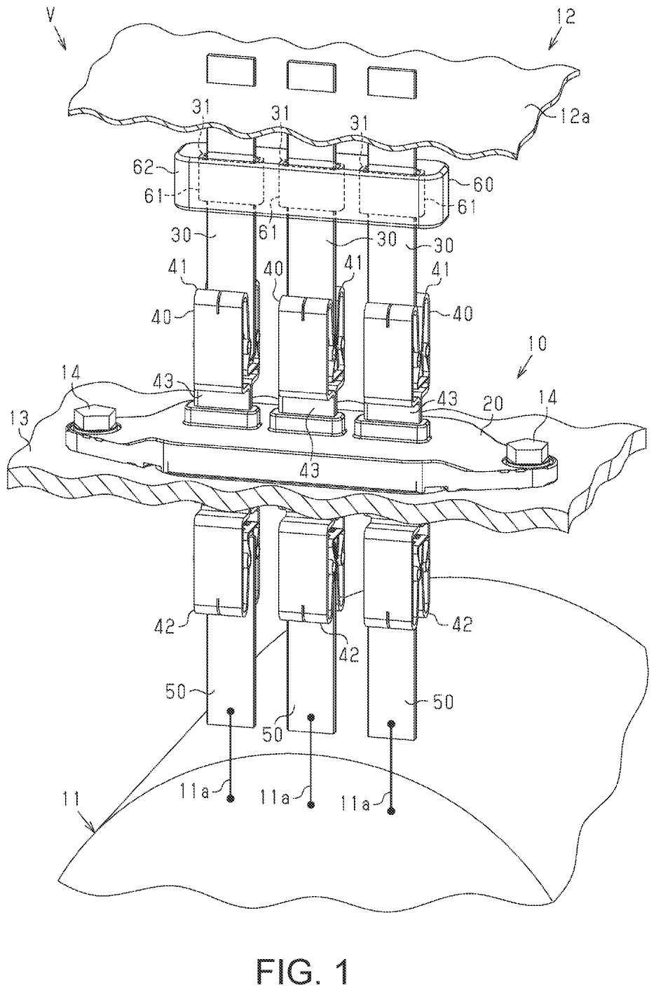

A terminal block 10 depicted in FIG. 1 is mounted in a vehicle V. The vehicle V is equipped with a motor 11 and an inverter 12. The motor 11 and the inverter 12 are electrical components mounted in the vehicle V. The motor 11 is housed inside a motor housing 13. The inverter 12 includes a circuit board 12a. The terminal block 10 is attached to the motor housing 13. As one specific example, the terminal block 10 is fixed to the motor housing 13 by bolts 14. The terminal block 10 is then electrically connected to the motor 11 and the circuit board 12a of the inverter 12.

### Overall Configuration of Terminal Block 10

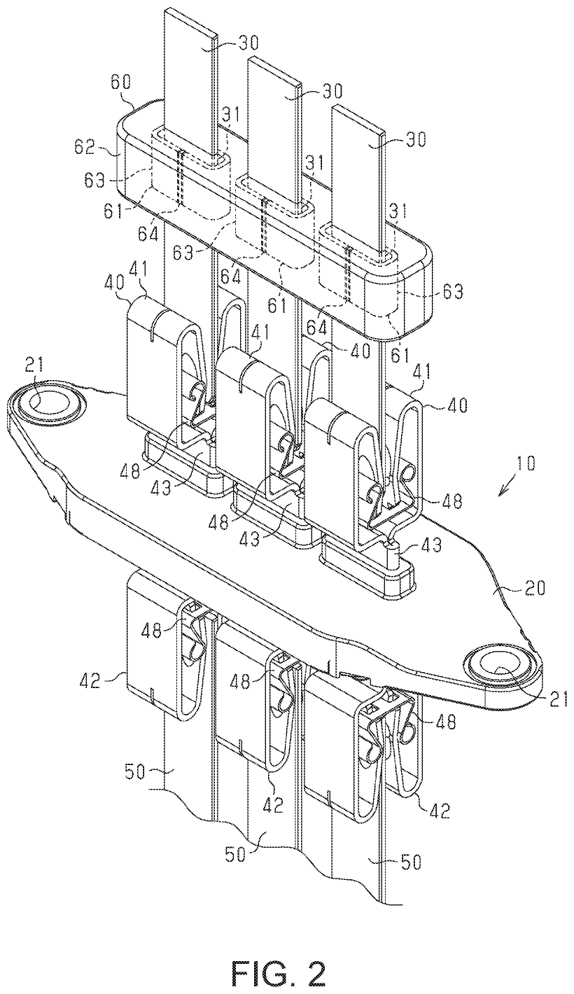

As depicted in FIG. 1 and FIG. 2, the terminal block 10 includes a housing 20, inverter terminals 30, junction terminals 40, motor terminals 50, and a current sensor 60. The terminal block 10 is equipped with three inverter terminals 30, three junction terminals 40, and three motor terminals 50 corresponding to the U phase, the V phase, and the W phase of the motor 11. Accordingly, the terminal block 10 includes a plurality of each of the inverter terminals 30, the junction terminals 40, and the motor terminals 50.

### Configuration of Inverter Terminals 30

Each inverter terminal 30 is a bus bar in the form of an elongated thin flat plate. The inverter terminals 30 each have the same thickness. The lengths of the inverter terminals 30 in the direction in which their long sides extend are the same. When the direction in which the short side of each inverter terminal 30 extends is regarded as the “width direction”, the respective inverter terminals 30 also have the same widths. The inverter terminals 30 are arranged so that their thickness directions are aligned and their width directions are also aligned. A first end portion located at one end in the length direction of each inverter terminal 30 is electrically connected to the circuit board 12a of the inverter 12. Accordingly, the respective inverter terminals 30 are “first terminals” that are electrically connected to the inverter 12, which is an electrical component. A second end portion located at the other end in the length direction of each inverter terminal 30 is electrically connected to a junction terminal 40.

Each inverter terminal 30 includes a flat plate portion 31 (flat plate) that is surrounded by the current sensor 60. The flat plate portion 31 of each inverter terminal 30 passes through an inner portion of the current sensor 60. The current sensor 60 is integrated with the respective inverter terminals 30.

### Configuration of Motor Terminals 50

Each motor terminal 50 is a bus bar in the form of an elongated thin flat plate. The motor terminals 50 each have the same thickness. The lengths of the motor terminals 50 in the direction in which their long sides extend are the same. When the direction in which the short side of each motor terminal 50 extends is regarded as the “width direction”, the respective motor terminals 50 also have the same widths. The motor terminals 50 are arranged so that their thickness directions are aligned and their width directions are also aligned. First end portions located at one end in the length direction of the respective motor terminals 50 are electrically connected to motor leads 11a that extend from a U phase coil, a V phase coil, and a W phase coil of the motor 11. Note that the first end portions of the motor terminals 50 and the motor leads 11a are connected via connector terminals, not illustrated. The motor terminals 50 are electrically connected to the motor 11 via the motor leads 11a. Accordingly, the motor terminals 50 are “first terminals” that are electrically connected to the motor 11, which is an electrical component. Note that the motor leads 11a are schematically depicted in FIG. 1. A second end portion located at the other end in the length direction of each motor terminal 50 is electrically connected to a junction terminal 40.

### Overall Configuration of Junction Terminals 40

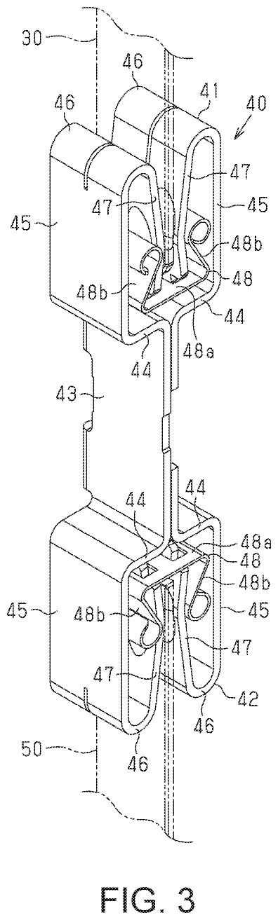

As depicted in FIG. 3, each junction terminal 40 includes a first clip portion 41 and a second clip portion 42, which are clip portions (clips), and a connecting portion 43. Each first clip portion 41 clamps the second end portion of an inverter terminal 30. Each junction terminal 40 is electrically connected to an inverter terminal 30 by the first clip portion 41 clamping the inverter terminal 30. The second clip portion 42 clamping the second end portion of a motor terminal 50. Each junction terminal 40 is also electrically connected to a motor terminal 50 by the second clip portion 42 clamping the motor terminal 50. Accordingly, each junction terminal 40 is a “second terminal” that is electrically connected to an inverter terminal 30 and a motor terminal 50, which are “first terminals”.

The connecting portion 43 is connected to the first clip portion 41 and the second clip portion 42. The connecting portion 43 is in the form of an elongated flat plate. The first clip portion 41 is connected to a first end portion of the connecting portion 43 that is positioned at one end in a length direction in which the long sides of the connecting portion 43 extend. The second clip portion 42 is connected to a second end portion that is positioned at the other end in the length direction of the connecting portion 43.

### Configuration of First Clip Portion 41 and Second Clip Portion 42

Since the first clip portion 41 and the second clip portion 42 have the same configuration, in the following description, the configuration of the first clip portion 41 is described in detail, the same reference numerals are assigned to the configuration of the second clip portion 42, and the description thereof is simplified.

The first clip portion 41 has a pair of base portions 44, a pair of extending portions 45, a pair of bent portions 46, and a pair of clamping portions 47 (clamps). The base portions 44 are in the form of thin flat plates that extend in opposite directions from the first end portion of a connecting portion 43. Note that the base portions 44 of the second clip portion 42 extend in opposite directions from the second end portion of the connecting portion 43. The directions in which the base portions 44 extend from the connecting portion 43 match the thickness direction of the connecting portion 43.

The extending portions 45 are in the form of elongated thin flat plates that extend in the thickness direction of the base portions 44 from end portions of the respective base portions 44 at opposite ends to the connecting portion 43. The extending portions 45 have the same length. The extending portions 45 extend in parallel to each other. The bent portions 46 are continuous with end portions of the respective extending portions 45 at opposite ends to the base portions 44. The bent portions 46 are formed as curved plates that are curved into arc shapes. The bent portions 46 are curved from the extending portions 45 so as to approach each other.

The clamping portions 47 are formed as elongated thin flat plates that extend toward the base portions 44 from end portions of the bent portions 46 at opposite ends to the extending portions 45. The clamping portions 47 become gradually separated from the extending portions 45 as the distance from the bending portions 46 increases. Accordingly, the respective clamping portions 47 extend at angles that intersect the directions in which the extending portions 45 extend. Front ends of the clamping portions 47 are separated from the base portions 44. The pair of clamping portions 47 of a first clip portion 41 clamp an inverter terminal 30, which is a bus bar. The pair of clamping portions 47 of a second clip portion 42 clamp a motor terminal 50, which is also a bus bar.

The first clip portion 41 and the second clip portion 42 each include a biasing member 48 (spring). Each biasing member 48 includes a connecting portion 48a and a pair of biasing portions 48b. The connecting portion 48a is formed as an elongated thin flat plate. The biasing portions 48b are thin plates that extend from both edges of the connecting portion 48a in the short side direction. Each biasing portion 48b extends at an angle from both edges of the connecting portion 48a in a direction so as to intersect the direction in which the connecting portion 48a extends. The biasing portions 48b extend in directions so as to approach each other as the distance from the connecting portion 48a increases.

A biasing member 48 is attached to front end portions of each pair of clamping portions 47. The pair of clamping portions 47 are disposed between the pair of biasing portions 48b. When the pair of clamping portions 47 have been disposed between the pair of biasing portions 48b, the biasing portions 48b will become displaced so as to move away from each other with the connecting portion 48a side end portions of the biasing portions 48b as pivots. The biasing portions 48b bias the clamping portions 47 so that the clamping portions 47 try to return to their original positions before the clamping portions 47 were displaced in the direction away from each other. In this way, since the biasing portions 48b bias the pair of clamping portions 47 of the first clip portion 41 for example toward each other, when an inverter terminal 30 is disposed between the pair of clamping portions 47, the inverter terminal will be stably clamped by the pair of clamping portions 47. Likewise, since the biasing portions 48b bias the pair of clamping portions 47 of the second clip portion 42 for example toward each other, when a motor terminal 50 is disposed between the pair of clamping portions 47, the motor terminal 50 will be stably clamped by the pair of clamping portions 47. Accordingly, the biasing member 48 biases the pair of clamping portions 47 in a direction where the clamping portions 47 approach each other.

### Configuration of Housing 20

As depicted in FIG. 2, the housing 20 is made of resin. The housing 20 is formed as a plate. The housing 20 has bolt insertion holes 21 through which the bolts 14 can be inserted. The housing 20 holds the junction terminals 40. In more detail, the housing 20 holds part of the connecting portion 43 of each junction terminal 40. The junction terminals 40 and the housing 20 are integrated by insert molding.

### Configuration of Current Sensor 60

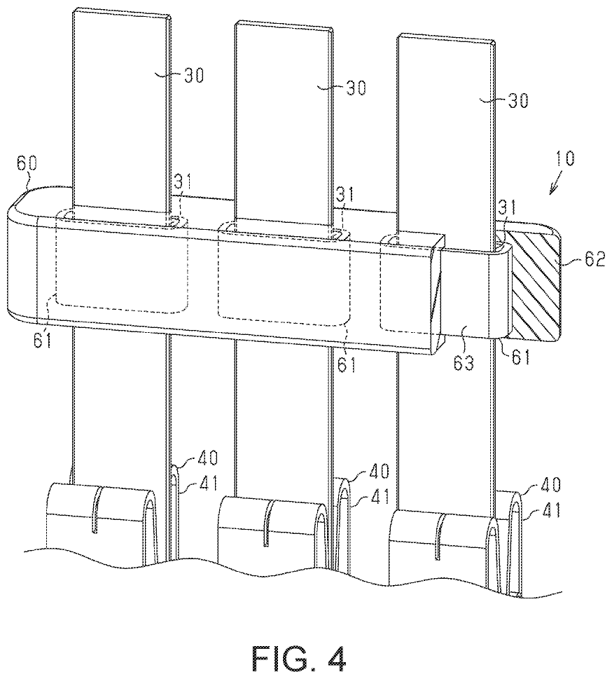

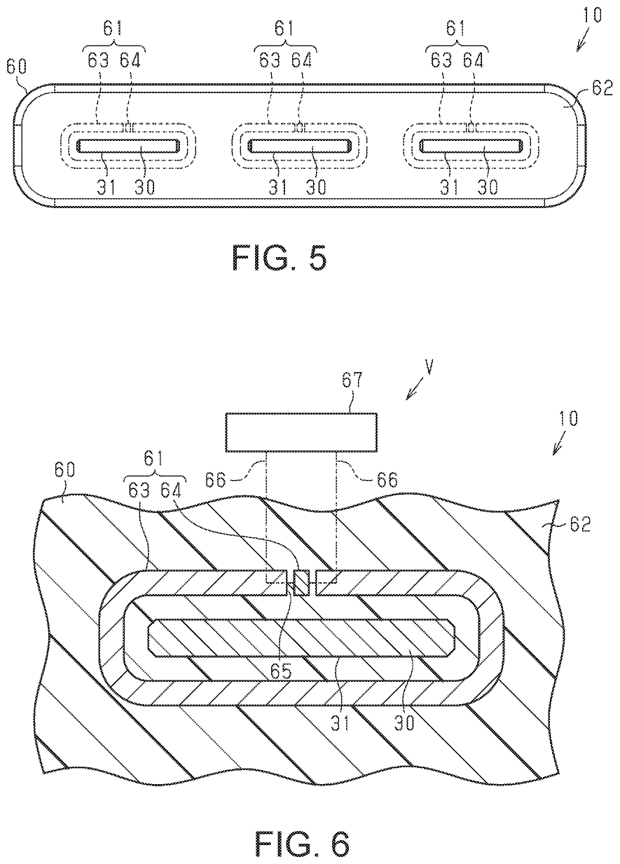

As depicted in FIGS. 4 and 5, the current sensor 60 is integrated with the flat plate portion 31 of each inverter terminal 30. The current sensor 60 includes sensor components 61 (sensors) that are provided corresponding to each inverter terminal 30 and a base member 62 (base) that incorporates the plurality of sensor components 61. The base member 62 is made of resin. The base member 62 is formed as a rectangular block. The direction in which the long sides of the base member 62 extend matches the width direction of the inverter terminals 30. The base member 62 surrounds the flat plate portions 31 of the inverter terminals 30.

As depicted in FIG. 6, each sensor component 61 includes a core member 63 and a Hall element 64. Each core member 63 is a C-shaped ferrite core. Accordingly, a gap 65 is formed in part of each core member 63. Each core member 63 is disposed so as to surround the flat plate portion 31 of an inverter terminal 30. Each Hall element 64 is disposed in the gap 65 of a core member 63. Each Hall element 64 is electrically connected to a vehicle ECU 67 via wiring 66. The base member 62, the flat plate portions 31 of the inverter terminals 30, the core members 63, and the Hall elements 64 are integrated by insert molding.

### Operation of the First Embodiment

Next, the operation of the first embodiment will be described.

Currents flowing from the circuit board 12a of the inverter 12 to the inverter terminals are supplied to the motor 11 via the junction terminals 40, the motor terminals 50, and the motor leads 11a. When a current flows from the circuit board 12a of the inverter 12 to an inverter terminal 30, magnetic flux is generated in the core member 63 and this magnetic flux generated in the core member 63 passes through the Hall element 64. As a result, the Hall element 64 generates a Hall voltage based on the magnetic flux. The Hall voltage is proportional to the current value of the current flowing through that inverter terminal 30. Accordingly, the current sensor 60 can be said to detect the currents flowing through the respective inverter terminals 30.

A signal relating to the Hall voltage generated by each Hall element 64 is outputted via the wiring 66 to the vehicle ECU 67. The vehicle ECU 67 controls driving of the inverter 12 based on the signals outputted from the respective Hall elements 64 so that the current value supplied from the inverter 12 to the motor 11 becomes a desired current value. When the current value supplied from the inverter 12 to the motor 11 becomes the desired current value, the motor 11 will rotate at a desired rotational speed. Accordingly, the driving of the inverter 12 is controlled by the current sensor 60 detecting the currents flowing through the respective inverter terminals 30, and as a result, control is performed over the driving of the motor 11.

The following effects can be obtained by the first embodiment.

(1-1) The current sensor 60 that detects the currents flowing through the inverter terminals is integrated with the inverter terminals 30. By using this configuration, since the inverter 12 does not need to be provided with the current sensor 60, unlike for example a configuration in which the inverter 12 is provided with the current sensor 60, a situation where there is a corresponding increase in the size of the inverter 12 due to the provision of the current sensor 60 is avoided. This can contribute to miniaturization of the inverter 12.
(1-2) Each junction terminal 40 includes a first clip portion 41 and a second clip portion 42. The inverter terminals 30 are bus bars in the form of flat plates that are clamped by the first clip portions 41 and the motor terminals 50 are bus bars in the form of flat plates that are clamped by the second clip portions 42. By using this configuration, since the inverter terminals 30 and the junction terminals 40 can be connected by merely clamping the inverter terminals 30 with the first clip portions 41, there is no need to separately provide components for connecting the inverter terminals 30 and the junction terminals 40 for example, which makes it possible to miniaturize the terminal block 10 itself. In addition, it is possible to easily electrically connect the inverter terminals 30 and the junction terminals 40 while absorbing the respective dimensional tolerances of the inverter terminals 30 and the junction terminals 40. Likewise, since the motor terminals 50 and the junction terminals 40 can be connected by simply clamping the motor terminals 50 with the second clip portions 42, there is no need to separately provide components for connecting the motor terminals 50 and the junction terminals 40 for example, which makes it possible to miniaturize the terminal block itself. In addition, it is possible to easily electrically connect the motor terminals 50 and the junction terminals 40 while absorbing the respective dimensional tolerances of the motor terminals 50 and the junction terminals 40.
(1-3) The junction terminals 40 each include a first clip portion 41 and a second clip portion 42. The inverter terminals 30 and the motor terminals 50 are bus bars. By using this configuration, since it is possible to simplify the configurations of the inverter terminals 30 and the motor terminals 50, it is possible for example to avoid the problem of the designs of components in the peripheries of the inverter terminals 30 and the motor terminals 50 having to be changed due to the configurations of the inverter terminals 30 and the motor terminals 50 being complex.
(1-4) The inverter terminals 30 each have a flat plate portion 31 that is surrounded by the current sensor 60. By using this configuration, since the inverter terminals 30 have the flat plate portions 31 that are surrounded by the current sensor 60, it is easy to integrate the current sensor 60 with the inverter terminals 30.
(1-5) The first clip portions 41 each include a pair of clamping portions 47 that clamp an inverter terminal 30, and a biasing member 48 that biases the pair of clamping portions 47 toward each other. By using this configuration, at each first clip portion 41, the biasing member 48 biases the pair of clamping portions 47 in a direction toward each other, which makes it possible to stably clamp an inverter terminal 30 with the pair of clamping portions 47. Accordingly, the electrical connections between the inverter terminals 30 and the junction terminals 40 can be stabilized, which improves reliability. Likewise, the second clip portions 42 each include a pair of clamping portions 47 that clamp a motor terminal 50, and a biasing member 48 that biases the pair of clamping portions 47 in a direction toward each other. By using this configuration, at each second clip portion 42, the biasing member 48 biases the pair of clamping portions 47 in a direction toward each other, which makes it possible to stably clamp a motor terminal 50 with the pair of clamping portions 47. Accordingly, the electrical connections between the motor terminals 50 and the junction terminals 40 can be stabilized, which improves reliability.
(1-6) The current sensor 60 includes the sensor components 61, which are provided corresponding to the inverter terminals 30, and the base member 62 that incorporates the plurality of sensor components 61. By using this configuration, since the current sensor 60 includes the base member 62 which incorporates the sensor components 61 that are provided corresponding to the respective inverter terminals 30, it is possible to simplify the task of disposing the sensor components 61 so as to correspond to the individual inverter terminals 30.

### Second Embodiment

Next, a second embodiment of a terminal block will be described. Note that the description of the embodiment given below will focus on differences from the first embodiment, the same reference numerals have been assigned to configurations that are the same as in the first embodiment, and some or all of the description of such configurations is omitted.

### Configuration of Junction Terminals 70

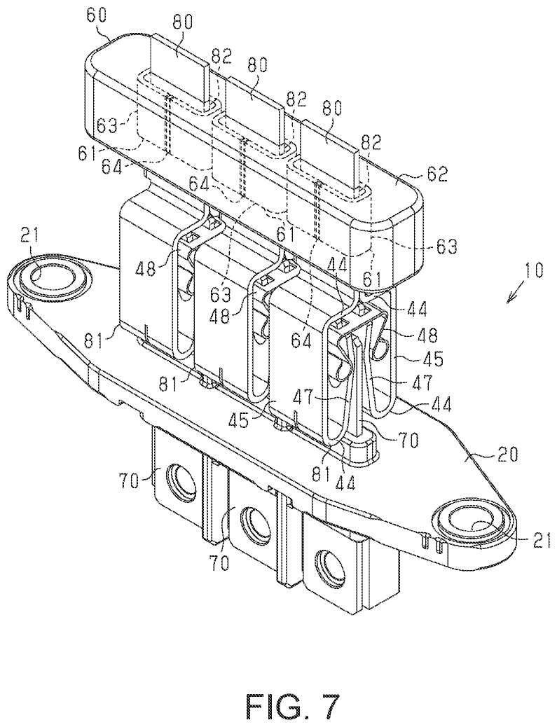

As depicted in FIG. 7, each junction terminal 70 is a bus bar in the form of an elongated thin flat plate. The junction terminals 70 each have the same thickness. The lengths of the junction terminals 70 in the direction in which their long sides extend are the same. When the direction in which the short side of each junction terminal 70 extends is regarded as the “width direction”, the respective junction terminals 70 also have the same widths. The junction terminals 70 are arranged so that their thickness directions are aligned and their width directions are also aligned. First end portions located at one end in the length direction of the respective junction terminals 70 are electrically connected to inverter terminals 80. Accordingly, each junction terminal 70 is a “second terminal” that is electrically connected to an inverter terminal 80, which is a “first terminal”. Note that a second end portion located at the other end in the length direction of each junction terminal 70 is electrically connected to a motor terminal, not illustrated.

### Configuration of Inverter Terminals 80

Each inverter terminal 80 is a first terminal that is electrically connected to the inverter 12, which is an electrical component. Each inverter terminal 80 includes a clip portion 81 and a flat plate portion 82 that extends from the clip portion 81. Since the configuration of the clip portion 81 is the same as the configuration of the first clip portion 41 and the second clip portion 42 described in the first embodiment, the same reference numerals have been assigned and detailed description is omitted.

Each clip portion 81 clamps a first end portion of a junction terminal 70. Each inverter terminal 80 is electrically connected to a junction terminal 70 by clamping the first end portion of the junction terminal 70 with the clip portion 81. The flat plate portion 82 is formed as an elongated thin plate that extends from the clip portion 81. The flat plate portion 82 of each inverter terminal 80 is surrounded by the current sensor 60. The flat plate portion 82 of each inverter terminal 80 passes through an inner portion of the current sensor 60. The current sensor 60 is integrated with the inverter terminals 80.

Accordingly, as described in the first embodiment and this second embodiment, one of the inverter terminals 30 or 80 and the junction terminals 40 or 70 may include a clip portion, and the other of the inverter terminals 30 or 80 and the junction terminals 40 or 70 may include a bus bar in the form of a flat plate that is clamped by the clip portion.

Since a description of the operation of the second embodiment would be the same as the description of the operation of the first embodiment, detailed description is omitted here.

With the second embodiment, in addition to the effects (1-1), (1-5), and (1-6) of the first embodiment, the following effects can be obtained.

(2-1) Each inverter terminal 80 includes a clip portion 81. Each junction terminal 70 is a bus bar in the form of a flat plate that is clamped by the clip portion 81. By using this configuration, since it is possible to connect the inverter terminals 80 and the junction terminals 70 by merely clamping the junction terminals 70 with the clip portions 81, there is no need to separately provide components for connecting the inverter terminals 80 and the junction terminals 70 for example, which makes it possible to miniaturize the terminal block itself. In addition, it is possible to easily electrically connect the inverter terminals 80 and the junction terminals 70 while absorbing the respective dimensional tolerances of the inverter terminals 80 and the junction terminals 70.
(2-2) The junction terminals 70 are bus bars and the inverter terminals 80 include the clip portions 81. By using this configuration, since it is possible to simplify the configurations of the junction terminals 70, it is possible for example to avoid the problem of the designs of components in the peripheries of the junction terminals 70 having to be changed due to the configurations of the junction terminals 70 being complex.
(2-3) The inverter terminals 80 include a flat plate portion 82 that extends from the clip portion 81 and is surrounded by the current sensor 60. By using this configuration, since the inverter terminals 80 have the flat plate portions 82 that extend from the clip portions 81 and are surrounded by the current sensor 60, it is easy to integrate the current sensor 60 with the inverter terminals 80.

### Third Embodiment

Next, a third embodiment of a terminal block will be described.

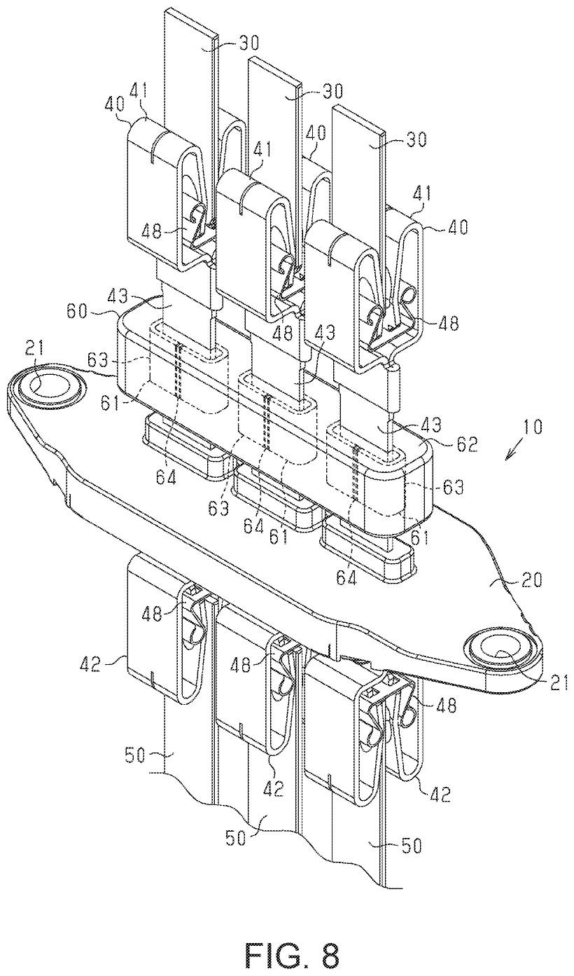

As depicted in FIG. 8, the current sensor 60 is integrated with the connecting portions 43 of the junction terminals 40. The lengths by which the connecting portions 43 of the respective junction terminals 40 protrude from the housing 20 as set so that the protruding lengths of parts on the first clip portion 41 side differ from the protruding lengths of parts on the second clip portion 42 side. In more specific terms, the protruding length by which part of each connecting portion 43 protrudes from the housing 20 on the first clip portion 41 side is longer than the protruding length by which part of each connecting portion 43 protrudes from the housing 20 on the second clip portion 42 side. The current sensor 60 is integrated with parts of the connecting portions 43 of the junction terminals 40 between the housing 20 and the first clip portions 41.

The sensor components 61 of the current sensor 60 are provided corresponding to the respective junction terminals 40. The core members 63 of the respective sensor components 61 are disposed so as to surround the connecting portions 43 of the junction terminals 40. The base member 62, the connecting portions 43 of the junction terminals 40, the core members 63, and the Hall elements 64 are integrated by insert molding.

When a current flows from the circuit board 12a of the inverter 12 to a junction terminal 40 via an inverter terminal 30, magnetic flux is generated in the core member 63, and this magnetic flux generated in the core member 63 passes through the Hall element 64. As a result, the Hall element 64 generates a Hall voltage based on the magnetic flux. The Hall voltage is proportional to the value of the current flowing through that junction terminal 40. Accordingly, the current sensor 60 can be said to detect the currents flowing through the respective junction terminals 40.

Accordingly, as described in the first embodiment, the second embodiment, and this third embodiment, the current sensor 60 that detects the currents flowing through the inverter terminals 30 or 80 or the junction terminals 40 or 70 may be integrated with the inverter terminals 30 or 80 or the junction terminals 40 or 70. Also, the sensor components 61 may be provided corresponding to the inverter terminals 30 or 80 or the junction terminals 40 or 70.

Since a description of the operation of the third embodiment would be the same as the description of the operation of the first embodiment, detailed description is omitted here.

With the third embodiment, in addition to the effects (1-1), (1-2), (1-3), (1-5), and (1-6) of the first embodiment, the following effect can be obtained.

(3-1) The current sensor 60 is integrated with parts of the connecting portions 43 of the junction terminals 40 between the housing 20 and the first clip portions 41. This configuration eliminates the need for design changes, such as making the inverter terminals 30 longer to provide enough space for integrating the current sensor 60, as in the case where the current sensor 60 is integrated with the inverter terminals 30 for example. Accordingly, it is possible to simplify the configuration of the inverter terminals 30.

### Fourth Embodiment

Next, a fourth embodiment of a terminal block will be described.

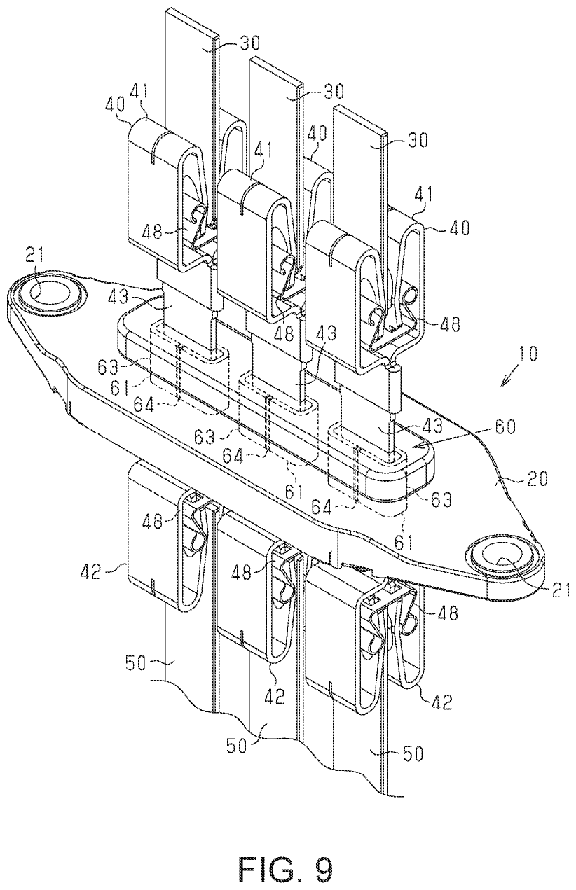

As depicted in FIG. 9, the current sensor 60 is integrated with the housing 20. The respective sensor components 61 of the current sensor 60 are provided corresponding to the individual junction terminals 40. The core member 63 of each sensor component 61 is disposed so as to surround the connecting portion 43 of each junction terminal 40. The core members 63 and the Hall elements 64 of the respective sensor components 61 are embedded in the housing 20. The housing 20, the connecting portions 43 of the respective junction terminals 40, the core members 63, and the Hall elements 64 are integrated by insert molding.

When a current flows from the circuit board 12a of the inverter 12 to a junction terminal 40 via an inverter terminal 30, magnetic flux is generated in the core member 63, and this magnetic flux generated in the core member 63 passes through each Hall element 64. As a result, the Hall element 64 generates a Hall voltage based on the magnetic flux. The Hall voltage is proportional to the value of the current flowing through that junction terminal 40. Accordingly, the current sensor 60 can be said to detect the current flowing through each junction terminal 40.

Since a description of the operation of the fourth embodiment would be the same as the description of the operation of the first embodiment, detailed description is omitted here.

With the fourth embodiment, in addition to the effects (1-1), (1-2), (1-3), (1-5), and (1-6) of the first embodiment, the following effect can be obtained.

(4-1) The current sensor 60 is integrated with the housing 20. This configuration eliminates the need for design changes, such as making the inverter terminals 30 or the connector portions 43 of the junction terminals 40 longer to provide enough space to integrate the current sensor 60, such as when the current sensor 60 is integrated with the inverter terminals 30 or the current sensor 60 is integrated with the junction terminals 40. Accordingly, it is possible to simplify the configuration of the inverter terminals 30 and/or the junction terminals 40.

Modifications

It should be noted that the above-described embodiments can be implemented with the following modifications. The embodiments described above and the following modifications may be implemented in combination within a range where this remains technologically consistent.

In the first embodiment, it is possible to integrate the current sensor 60 with the motor terminals 50 without the current sensor 60 being integrated with the inverter terminals 30, for example. In this case, the motor terminals 50 each include a flat plate portion that is surrounded by the current sensor 60. By using this configuration, it is not necessary for the motor 11 to be equipped with the current sensor 60, even when the current sensor 60 is placed within the motor housing 13 due to space requirements relating to placement of the current sensor 60. For this reason, unlike the case where the motor 11 is provided with a current sensor 60 for example, there is no corresponding increase in the size of the motor 11 due to the provision of the current sensor 60. Accordingly, this contributes to miniaturization of the motor 11.

In the third embodiment, instead of integrating the current sensor 60 with parts of the connecting portions 43 of the junction terminals 40 located between the housing 20 and the first clip portions 41, it is also possible to integrate the current sensor 60 with the parts of the connecting portions 43 of the junction terminals 40 located between the housing 20 and the second clip portions 42. In this case, the length by which the second clip portion 42 side parts of the connecting portions 43 protrude from the housing 20 are longer than the length by which the first clip portion 41 side parts of the connecting portions 43 protrude from the housing 20.

In the above embodiments, there are no particular limitations on the configuration of the first clip portions 41, the second clip portions 42, or the clip portions 81. As examples, if the pair of clamping portions 47 themselves are capable of sufficiently clamping the inverter terminals 30, the motor terminals 50, or the junction terminals 70, which are bus bars, the first clip portions 41, the second clip portions 42, or the clip portions 81 may have configurations that omit the biasing members 48.

In the above embodiments, there are no particular limitations on the configuration of the respective sensor components 61 of the current sensor 60. Each sensor component 61 may be configured with a winding wound around an annular core member, for example, without using the Hall element 64.

In the above embodiments, there are no particular limitations on the respective numbers of the inverter terminals 30 or 80, the junction terminals 40 or 70, and the motor terminals 50 provided that the respective numbers of the inverter terminals 30 or 80, the junction terminals 40 or 70, and the motor terminals 50 are the same.

Although the terminal block 10 electrically connects the motor 11 and the inverter 12 in the embodiments described above, this is not a limitation and the terminal block 10 may electrically connect electrical components aside from the motor 11 and the inverter 12.

In the illustrated embodiments, electrical paths that include first and second electrical component terminals, which may be the inverter terminals 30 and the motor terminals 50, and the junction terminals 40 of the terminal block 10 positioned between the first and second electrical component terminals are referred to as structures that conduct electricity between components. As depicted in FIG. 1, the terminal block 10 may be configured so that the inverter terminals 30 and the motor terminals 50 are electrically connected via the junction terminals 40 without using flexible electric wires, such as wire harnesses, between such components.

As depicted in FIG. 1, the housing 20 of the terminal block 10 may include a first housing surface that is fixed to an outer surface of a first electrical component, which may be the motor 11, or may face an outer surface of the first electrical component and a second housing surface that faces the outer surface of a second electrical component, which may be the inverter 12. As depicted in FIG. 1, a gap may be formed between the second housing surface of the housing 20 and the outer surface of the second electrical component, which may be the inverter 12. As one example, the current sensor 60 may be disposed in a gap between the second housing surface of the housing 20 and the outer surface of the second electrical component, which may be the inverter 12.

As depicted in FIGS. 1 and 3, the two clip portions 41 and 42 of one junction terminal in the terminal block 10 may be free ends of the junction terminal 40. The connecting portion 43 between the two clip portions 41 and 42 of one junction terminal 40 may be located at an intermediate position along the length of the junction terminal 40. As depicted in FIGS. 1 and 2, the connecting portion 43 of each junction terminal 40 may be held in a fixed manner by the housing 20. The junction terminals 40 may linearly pass through the housing 20, for example. One out of the two clip portions 41 and 42 may protrude linearly from a first housing surface of the housing 20 and the other out of the two clip portions 41 and 42 may protrude linearly from a second housing surface of the housing 20. In one example, the clip portions 41 may allow limited sliding between the junction terminals 40 and the inverter terminals 30, and the clip portions 42 may allow limited sliding between the junction terminals and the motor terminals 50. Such clipping by the clip portions 41 and 42 is advantageous in absorbing dimensional tolerances and assembly tolerances in the length direction and/or the width direction and/or the thickness direction between the junction terminals 40, the inverter terminals 30 and the motor terminals 50.

### Appendix 1

As depicted in FIGS. 1, 2, 7, and the like, a terminal block 10 according to a number of aspects of the present disclosure may include a housing 20, second terminals 40 or 70 that extend vertically with respect to the housing 20, and two first terminals 30, 50, or 80 that are connected to both ends of the second terminals 40 or 70 and extend in the same direction as the second terminals 40 or 70,
electrical components 11 and 12 and the first terminals 30, 50, or 80 may be electrically connected,
the first terminals 30, 50, or 80 and the second terminals 40 or 70 may be electrically connected, and
a current sensor 60 that detects a current flowing through the first terminals 30, 50, or 80 or the second terminals 40 or 70 may be integrated with the housing 20, the first terminals 30, 50, or 80 or the second terminals 40 or 70.

### Appendix 2

As depicted in FIGS. 2, 7, 8, and 9, according to an aspect of the present disclosure, the direction in which the current sensor 60 extends may match the direction in which the housing 20 extends.

1. A terminal block comprising:
a first terminal electrically connected to an electrical component; and
a second terminal electrically connected to the first terminal,
wherein a current sensor for detecting a current that flows through the first terminal or the second terminal is integrated with the first terminal or the second terminal.

2. The terminal block according to claim 1, wherein:
one of the first terminal and the second terminal includes a clip, and
another of the first terminal and the second terminal is a bus bar formed as a flat plate that is clamped by the clip.

3. The terminal block according to claim 2, wherein:
the second terminal includes the clip, and
the first terminal is a bus bar.

4. The terminal block according to claim 2,
wherein the bus bar includes a flat plate that is surrounded by the current sensor.

5. The terminal block according to claim 2, wherein:
the second terminal is a bus bar, and
the first terminal includes the clip.

6. The terminal block according to claim 5,
wherein the first terminal includes a flat plate that extends from the clip and is surrounded by the current sensor.

7. The terminal block according to claim 2,
wherein the clip includes a pair of clamps for clamping the bus bar and a spring for biasing the pair of clamps toward each other.

8. The terminal block according to claim 1, further comprising
a plurality of pairs of the first terminal and the second terminal,
wherein the current sensor includes sensor components, which are provided corresponding to the respective first terminals or the respective second terminals, and a base that incorporates the plurality of sensor components.

9. A terminal block comprising:
a first terminal electrically connected to an electrical component;
a second terminal electrically connected to the first terminal; and
a housing that is made of resin and holds the second terminal,
wherein a current sensor for detecting a current that flows through the second terminal is integrated with the housing.
